(19) United States
(12) Patent Application Publication
(10) Pub. No.: US 2025/0132076 A1
(43) Pub. Date: Apr. 24, 2025

(54) SIGNAL PROCESSING CIRCUIT AND MEASUREMENT SYSTEM

(71) Applicants: Rohde & Schwarz GmbH & Co. KG, Muenchen (DE); Friedrich-Alexander-Universität Erlangen-Nürnberg, Erlangen (DE)

(72) Inventors: Stefan SOHR, Muenchen (DE); Andre SCHEDER, Erlangen (DE)

(21) Appl. No.: 18/492,962

(22) Filed: Oct. 24, 2023

(51) Int. Cl. H01C 17/242; B23K 26/38; H02H 9/00; H05K 3/00; H05K 3/02

(52) U.S. Cl. CPC H01C 17/242; B23K 26/38; H02H 9/00; H05K 3/0061; H05K 3/027; H05K 2203/107; H05K 2203/163

(57) ABSTRACT

A method of manufacturing an electric circuit includes: providing a signal conductor on a first side of a substrate; providing a resistor structure on the first side of the substrate, the resistor structure contacting the signal conductor; providing a first contacting structure on the first side of the substrate, the first contacting structure electrically connected to the resistor structure by a first electric connection, the first electric connection at least partially provided on the second side of the substrate; applying a test signal to the resistor structure via a measurement circuit contacting the first contacting structure and the signal conductor; determining at least one characteristic property of the first resistor structure based on the test signal; and trimming the resistor structure until the at least one characteristic property has a predefined nominal value or is less than a predefined nominal value by less than a predefined threshold.

### FILED OF THE DISCLOSURE

Embodiments of the present disclosure generally relate to a method of manufacturing an electric circuit. Embodiments of the present disclosure further relate to a test and/or measurement instrument.

### BACKGROUND

With signal frequencies becoming higher and higher, the requirements on tolerances of impedance characteristics of electric and electronic circuits processing the signals are steadily on the rise. For example, attenuators are used to protect electronic devices from excessive power levels that could damage the electronic device.

For such attenuators, resistor structures must be precisely manufactured with a resistance being in a narrow tolerance range. With frequencies becoming higher, e.g. if signals having a frequency of several 10 GHz or even several 100 GHz are to be attenuated, the resistor structures have to be smaller due to physical constraints, which further complicates manufacturing the electric circuit.

Thus, there is a need for a method of manufacturing an electric circuit that allows for complying with particularly small tolerances.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a method of manufacturing an electric circuit. In an embodiment, the method comprises providing a substrate with a first side and a second side that is opposite to the first side; providing a signal conductor on the first side of the substrate; providing a first resistor structure on the first side of the substrate, wherein the first resistor structure contacts the signal conductor; providing a first contacting structure on the first side of the substrate, wherein the first contacting structure is electrically connected to the first resistor structure by a first electric connection, such that the first contacting structure is electrically connected to the signal conductor via the first resistor structure, wherein the first electric connection is at least partially provided on the second side of the substrate. The method further comprises applying a test signal to the first resistor structure via a measurement circuit contacting the first contacting structure and the signal conductor; determining at least one characteristic property of the first resistor structure based on the test signal; and trimming the first resistor structure until the at least one characteristic property has a predefined nominal value or differs from a predefined nominal value by less than a predefined threshold.

Therein and in the following, the term “providing A on B” is understood to denote that the structure or component A is applied onto B either directly or indirectly. Further, the term “A and B are electrically connected” is understood to denote that an electrically conductive connection is provided between A and B, such that a current can flow between A and B via an electrical conductor. Likewise, the term “electric connection” is understood to denote an electrically conductive connection via an electrical conductor, for example without interruption, e.g. a continuous electrical conductor.

The method according to the present disclosure is based on the idea to provide an additional contacting structure, namely the first contacting structure, on the first side of the substrate. This additional contacting structure allows to more reliably establish a connection between the signal conductor, the first resistor structure, and a measurement instrument in order to determine the at least one characteristic property of the first resistor structure.

In other words, the first contacting structure serves as an auxiliary contact for conducting measurements on the first resistor structure, namely for determining the at least one characteristic property.

The method according to embodiments of the present disclosure allow to precisely trim the first resistor structure, even for very small resistor structures and signal conductors being configured to process signals having frequencies of several 10 GHz or even several 100 GHz.

In general, before trimming, the at least one characteristic property differs from the predefined nominal value by more than the predefined threshold.

By trimming the first resistor structure, i.e. by removing material from the first resistor structure, the value of the at least one characteristic quantity is lowered or raised until the at least one characteristic property has the predefined nominal value or differs from the predefined nominal value by less than the predefined threshold.

Thus, embodiments of the method allow for manufacturing the electric circuit with particularly low tolerances of the at least one characteristic property.

In general, the substrate comprises one or several dielectric materials. For example, the substrate may consist of or comprise at least one of ceramics, diamond, a foil, or a PCB substrate material.

According to an aspect of the present disclosure, the at least one characteristic property comprises, for example, a resistance. Accordingly, the first resistor structure is trimmed until the resistance of the first resistor structure is equal to a nominal resistance or deviates from the nominal resistance by less than a predefined resistance threshold.

Thus, before trimming, the resistance of the first resistor structure may be smaller than the nominal value and may differ from the nominal value by more than the predefined resistance threshold. By removing material from the first resistor structure, the resistance of the first resistor structure is increased until the resistance of the first resistor structure is equal to the nominal resistance or deviates from the nominal resistance by less than the predefined resistance threshold.

In an embodiment of the present disclosure, the first electric connection comprises at least one vertical interconnect access, such as a via, that interconnects the first side of the substrate with the second side of the substrate through the substrate. In general, the at least one via connects a portion of the first electric connection provided on the second side of the substrate with the first contacting structure, and/or a portion of the first electric connection provided on the second side of the substrate with the first resistor structure.

According to another aspect of the present disclosure, the first resistor structure, for example, is trimmed by a laser. Trimming of the first resistor structure by a laser allows to precisely remove material from the first resistor structure, such that the at least one characteristic property of the first resistor structure can be set with high precision, thereby further reducing manufacturing tolerances. Of course, other light sources may be used for trimming the first resistor structure.

Further, it will be appreciated that other suitable techniques may be used in order to trim the first resistor structure. For example, the first resistor structure may be trimmed by removing material mechanically, thermally, and/or chemically.

In a further embodiment of the present disclosure, the first resistor structure has a first end and a second end that is opposite to the first end, wherein the first resistor structure tapers from the first end towards the second end. It has turned out that this tapered form of the first resistor structure allows to trim the first resistor structure with high precision, while simultaneously avoiding unwanted damage to other components, for example the signal conductor.

A further aspect of the present disclosure, for example, provides that the first end is connected to the first contacting structure, wherein the second end is directly connected to the signal conductor. In other words, the narrow end of the first resistor structure directly contacts the signal conductor. The wide end of the first resistor structure is connected to the first contacting structure via the first electric connection.

In some embodiments, the first resistor structure is trimmed in an area around the first end, such that a width of the first end is reduced. This way, unwanted damage to the signal conductor and/or to other components provided near the second end (e.g. another resistor structure) can be avoided reliably, as the first resistor structure is trimmed at the end facing away from the second end, i.e. at the end facing away from the signal conductor.

In an embodiment of the present disclosure, the first resistor structure is trimmed symmetrically with respect to an axis of the first resistor structure extending between the first end and the second end. Thus, the first resistor structure may be axially symmetric with respect to that axis after trimming.

According to an aspect of the present disclosure, the first resistor structure has, for example, a first end and a second end that is opposite to the first end, wherein the first resistor structure has a constant width between the first end and the second end. Accordingly, the first resistor structure may have a rectangular shape. However, it is to be understood that the first resistor structure may have any other suitable shape.

An aspect of the present disclosure provides, for example, that a layer thickness of the signal conductor is larger than a layer thickness of the first resistor structure. Accordingly, a resistance of the first resistor structure is larger than a resistance of the signal conductor even if they consist of the same material(s).

In some embodiments, the layer thickness of the first resistor structure may be chosen such that a desired resistance of the first resistor structure is obtained.

In a further embodiment of the present disclosure, the first resistor structure is composed of a different material or different materials compared to the signal conductor. In general, the first resistor structure may be composed of a material or materials with a higher specific electrical resistance than the signal conductor.

In some embodiments, the signal conductor comprises or consists of gold. Alternatively or additionally, the first resistor structure comprises or consists of nickel and/or chrome. However, it is to be understood that the signal conductor may comprise or consist of any other suitable material(s) with low specific electrical resistance, for example copper. Likewise, it is to be understood that the first resistor structure may comprise or consist of any other suitable material(s) with higher specific electrical resistance than the signal conductor.

Another aspect of the present disclosure provides, for example, that a reference mass layer is provided on the second side of the substrate, wherein the first electric connection is electrically isolated from the reference mass layer during the trimming of the first resistor structure. By electrically isolating the first electric connection during the trimming of the first resistor structure, influences of other components on the determination of the at least one characteristic property due to additional electrical circuits (e.g. via one or more resistors arranged in a circle) are avoided. It has turned out that this allows to determine the at least one characteristic property of the first resistor structure with enhanced precision. Accordingly, the first resistor structure can be trimmed with enhanced precision, such that the tolerances related to the at least one characteristic property are further reduced. Thus, the manufacturing tolerances of the electric circuit are further reduced.

In some embodiments, a portion of the first electric connection provided on the second side of the substrate may be electrically connected to the reference mass layer after trimming of the first resistor structure, wherein the portion of the first electric connection provided on the second side of the substrate is electrically connected to the reference mass layer by applying a conductive glue, by soldering of a bonding wire, by soldering of a conductive plate, by soldering of a conductive film, by welding of a bonding wire, by welding of a conductive plate, and/or by welding of a conductive film. Thereby, the first resistor structure is electrically connected with the reference mass layer. Thus, there is a certain attenuation from the signal conductor to the reference mass layer. In this case, the reference mass layer may already be provided on the second side of the substrate.

In an embodiment of the present disclosure, the reference mass layer is established as a conductive base body that is provided separately from the substrate, wherein the second side of the substrate is attached to the base body after trimming of the first resistor structure, such that a portion of the first electric connection provided on the second side of the substrate is electrically connected to the base body. Accordingly, the first resistor structure can be trimmed without the influence of the reference mass layer, as the substrate and the conductive base body are separately provided components. After trimming of the first resistor structure, the second side of the substrate is attached to the base body, such that the first resistor structure is electrically connected with the reference mass layer.

According to another aspect of the present disclosure, the second side of the substrate is, for example, glued to the base body by a conductive glue, and/or wherein the substrate is screwed onto the base body with the second side facing the base body. Accordingly, the first resistor structure can be trimmed without the influence of the reference mass layer, as the substrate and the conductive base body are separately provided components. After trimming of the first resistor structure, the second side of the substrate is glued and/or screwed to the base body, such that the first resistor structure is electrically connected with the reference mass layer.

A further aspect of the present disclosure provides, for example, that the substrate is clamped onto the base body with the second side facing the base body. Accordingly, the first resistor structure can be trimmed without the influence of the reference mass layer, as the substrate and the conductive base body are separately provided components. After trimming of the first resistor structure, the second side of the substrate is clamped onto the base body, such that the first resistor structure is electrically connected with the reference mass layer.

In another embodiment of the present disclosure, the substrate is soldered and/or welded onto the base body with the second side facing the base body, wherein the portion of the first electric connection provided on the second side of the substrate is electrically connected to the base body by a solder joint and/or by a weld. Accordingly, the first resistor structure can be trimmed without the influence of the reference mass layer, as the substrate and the conductive base body are separately provided components. After trimming of the first resistor structure, the second side of the substrate is soldered and/or welded onto the base body, such that the first resistor structure is electrically connected with the reference mass layer.

In some embodiments, the method of manufacturing an electric circuit may further comprise one or more of the following steps, in any combination:
providing a second resistor structure on the first side of the substrate, wherein the second resistor structure contacts the signal conductor;
providing a second contacting structure on the first side of the substrate, wherein the second contacting structure is electrically connected to the second resistor structure by a second electric connection, such that the second contacting structure is electrically connected to signal conductor via the second resistor structure, wherein the second electric connection is at least partially provided on a second side of the substrate;
applying a test signal to the second resistor structure via a measurement circuit contacting the second contacting structure and the signal conductor;
determining at least one characteristic property of the second resistor structure based on the test signal; and
trimming the second resistor structure until the at least one characteristic property has a nominal value or differs from the nominal value by less than a predefined threshold.

In some embodiments, the electric circuit comprises at least two resistor structures. For example, the electric circuit may be an attenuator circuit, for example a π-attenuator.

The explanations, advantages and embodiments described above with respect to the first resistor structure, the first electric connection, and the first contacting structure likewise apply to the second resistor structure, the second electric connection, and the second contacting structure.

In a certain example, the first electric connection may be electrically isolated from the reference mass layer at least during trimming of the first resistor structure, and the second electric connection may be electrically isolated from the reference mass layer at least during trimming of the second resistor structure. This way, the resistor structures can be trimmed without the influence of the respective other resistor structure, i.e. a circular circuit comprising the at least two circuit resistor structured is avoided during trimming of the resistor structures, as the first contacting structure and the second contacting structure are electrically isolated from each other.

In some embodiments, the first resistor structure and the second resistor structure may be trimmed such that a resistance of the first resistor structure is equal to a resistance of the second resistor structure. However, it is to be understood that the resistances of the first resistor structure and the second resistor structure may be different from each other.

In some embodiments, the method described above can be used to manufacture an electric circuit comprising an arbitrary number of resistor structures that are connected in an arbitrary manner.

The resistances of the resistor structures may be pairwise equal and/or pairwise different from each other. In other words, the individual resistor structures can have an arbitrary resistance, respectively.

Embodiments of the present disclosure further provide a test and/or measurement instrument, comprising an electric circuit manufactured according to the method described above.

Regarding the advantages and further properties of the test and/or measurement instrument, reference is made to the explanations given above with respect to the method of manufacturing an electric circuit, which also hold for the test and/or measurement instrument and vice versa.

For example, the test and/or measurement instrument may be an oscilloscope, for example a digital oscilloscope, a network analyzer, a vector network analyzer, a measurement receiver, a signal analyzer, a spectrum analyzer, a signal generator, or any other type of test and/or measurement instrument.

### DESCRIPTION OF THE DRAWINGS

The foregoing aspects and many of the attendant advantages of the disclosed subject matter will become more readily appreciated as the same become better understood by reference to the following detailed description, when taken in conjunction with the accompanying drawings, wherein:

FIG. 1 schematically shows a test and/or measurement instrument according to an embodiment of the present disclosure;

FIG. 2 schematically shows a system for manufacturing an electronic circuit according to an embodiment of the present disclosure;

FIG. 3 shows an example of a flow chart of a method of manufacturing an electric circuit according to an embodiment of the present disclosure;

FIG. 4 shows a cross-sectional view of an electric circuit according to an embodiment of the present disclosure;

FIG. 5 shows a cross-sectional view of an electric circuit according to a further embodiment of the present disclosure;

FIG. 6 schematically show a top-down view of an electric circuit according to a further embodiment of the present disclosure; and

FIG. 7 schematically shows a top-down view of an electric circuit according to a further embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

FIG. 1 schematically shows a test and/or measurement instrument 10 in accordance with an embodiment of the disclosure. In general, the test and/or measurement instrument 10 is configured to conduct measurements on an electronic device under test. For example, the test and/or measurement instrument 10 may be an oscilloscope, for example a digital oscilloscope, a network analyzer, a vector network analyzer, a measurement receiver, a signal analyzer, a spectrum analyzer, a signal generator, or any other type of test and/or measurement instrument.

The test and/or measurement instrument 10 comprises an input/output (I/O) interface 12 that is configured to receive and/or output measurement signals. The test and/or measurement instrument 10 further comprises a signal processing circuit 14 that is connected to the I/O interface 12.

In general, the signal processing circuit 14 is configured to analyze measurement signals received from the I/O interface 12 and/or to generate a measurement signal that is output via the I/O interface 12. The signal processing circuit 14 comprises an electric circuit 16 and a plurality of further electronic components 18 that are configured to analyze the measurement signals received from the I/O interface 12 and/or to generate the measurement signal that is output via the I/O interface 12. For example, the electric circuit 16 is established as an attenuator circuit.

Accordingly, the electric circuit 16 may be configured to reduce a signal level of measurement signals received via the I/O interface 12 such that the electronic components 18 are protected from too high signal powers. Alternatively or additionally, the electric circuit 16 may be configured to reduce a signal level of a measurement signal generated by the electronic components 18, such that the signal level can be adjusted to a desired level.

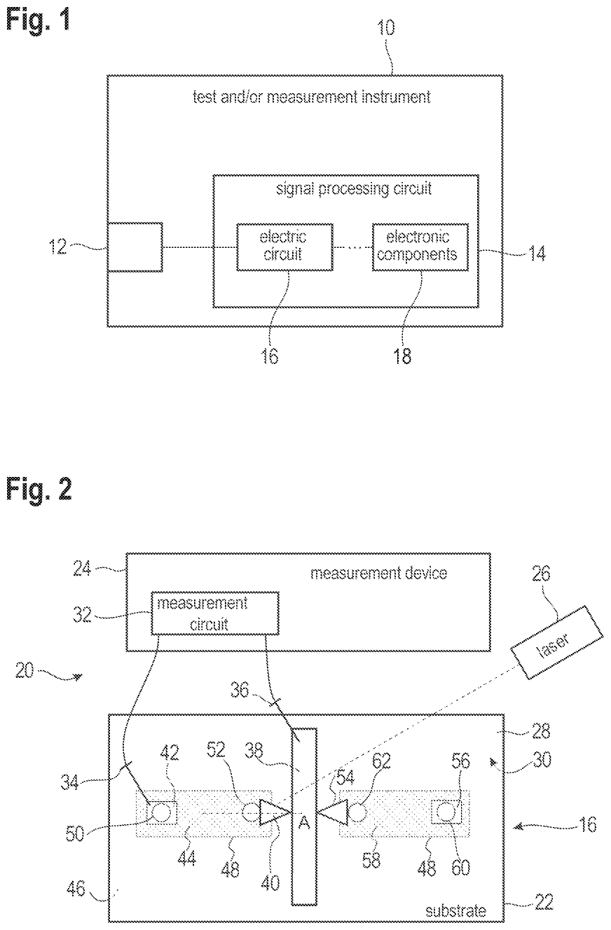

FIG. 2 schematically shows an example embodiment of a system 20 for manufacturing the electric circuit 16, wherein the electric circuit 16 is established as an attenuator. Without restriction of generality, this example is described in more detail in the following. However, it is to be understood that the concepts described hereinafter likewise apply to the manufacturing of other types of electric circuits, for example waveguide absorbers or impedance matching circuits.

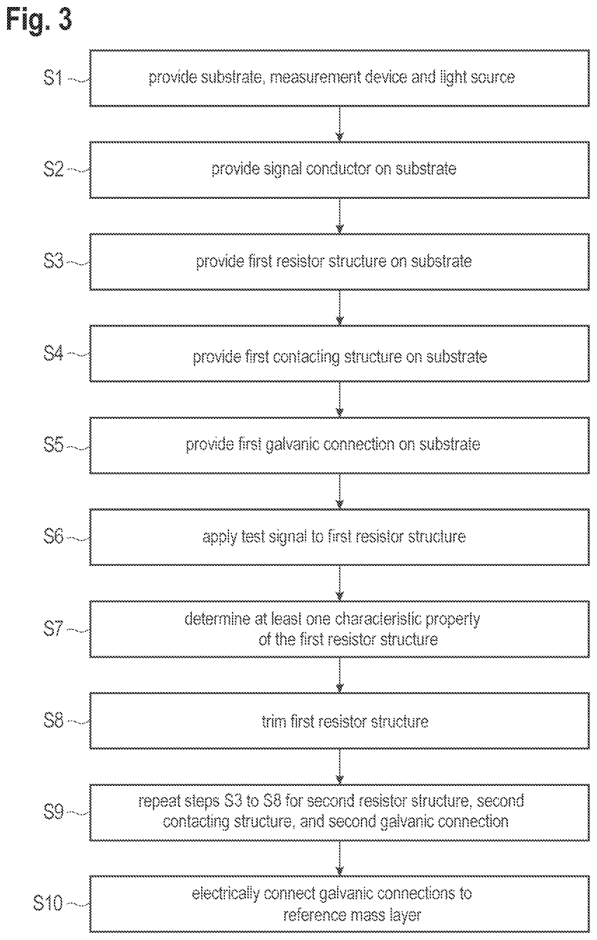

The system 20 is used to perform a method of manufacturing the electric circuit 16, an example of which is described in the following with reference to FIG. 3.

A substrate 22 for the electric circuit 16, a measurement device 24, and a light source 26 are provided (step S1).

The substrate 22 comprises a first side 28 that is visible in the top-down view shown in FIG. 2. The substrate 22 further comprises a second side 30 that is opposite to the first side 28.

In general, the substrate 22 consists of one or several dielectric materials. For example, the substrate 22 may consist of or comprise at least one of ceramics, diamond, a foil, or a PCB substrate material.

The measurement device 24 comprises a measurement circuit 32, a first measurement probe 34, and a second measurement probe 36, wherein the measurement probes are connected to the measurement circuit 32. For example, the measurement probes 34, 36 may be established as a needle probe, respectively.

In some embodiments, the light source 26 may be established as a laser or as any other suitable type of light source.

A signal conductor 38 is provided on or applied to the first side 28 of the substrate 22 (step S2). Therein and in the following, the term “provide” is understood to denote any suitable technique, for example galvanizing, sputtering, gluing, etching, and/or laser removal.

In general, the signal conductor 38 either comprises or consists of at least one material with a low specific electric resistance. For example, the signal conductor 38 may comprise or consist of gold and/or copper.

A first resistor structure 40 is provided or applied to the first side 28 of the substrate 22 such that the first resistor structure 40 directly contacts the signal conductor 38 (step S3). In general, the first resistor structure 40 consists of at least one material having a higher specific electric resistance than the signal conductor 38. For example, the first resistor structure 40 either comprises or consists of nickel and/or chrome.

A first contacting structure 42 is provided on or applied to the first side 28 of the substrate (step S4). In some embodiments, the first contacting structure 42 is spaced from the first resistor structure 40 such that there is no electric connection, i.e. no direct electric connection between the first contacting structure 42 and the first resistor structure 40 on the first side 28 of the substrate 22.

In general, the first contacting structure 42 either comprises or consists of at least one material with a low specific electric resistance, for example of the same material(s) as the signal conductor 38. For example, the first contacting structure 42 may comprise or consist of gold and/or copper.

In some embodiments, the first contacting structure 42 may have a rectangular shape. However, it is to be understood that the first contacting structure 42 may have any other suitable shape.

A first electric connection 44 is provided on or applied to the second side 30 of the substrate 22 (step S5). In general, the first electric connection 44 either comprises or consists of at least one material with a low specific electric resistance, for example of the same material(s) as the signal conductor 38. For example, the first electric connection 44 may comprise or consist of gold and/or copper.

It is noted that the substrate 22 may comprise a reference mass layer 46 that is provided on or applied to the second side of the substrate 22. In this case, an electric isolation 48 may be provided between the first electric connection 44 and the reference mass layer 46. For example, the electric isolation 48 may be established as a gap between the first electric connection 44 and the reference mass layer 46.

In some embodiments, the first electric connection 44 is electrically connected to the first contacting structure 42 by a first via 50. Further, the first electric connection 44 is electrically connected to the first resistor structure 40 by a second via 52. Accordingly, the first contacting structure 42 is electrically connected to the signal conductor 38 by the first via 50, the first electric connection 44, the second via 52, and the first resistor structure 40.

In some embodiments, a first end of first resistor structure 40 contacts the second via 52, while a second end of the first resistor structure 40 that is opposite to the first end contacts the signal conductor 38 directly.

As is shown in the embodiment of FIG. 2, the first resistor structure 40 may taper from the first end towards the second end, i.e. a width of the first resistor structure 40 decreases between the first end and the second end. Alternatively, the first resistor structure 40 may have a constant width between the first end and the second end.

A test signal is applied to the first resistor structure 40 by the measurement circuit 32 (step S6). In some embodiments, the test signal is generated by the measurement circuit 32 and is applied to the first resistor structure 40 via the first measurement probe 34 contacting the first contacting structure 42 and via the second measurement probe 36 contacting the signal conductor 38.

In some embodiments, the test signal may be a direct current signal or an alternating current signal. In some embodiments, the test signal may be an alternating current signal having a frequency of up to 10 MHz, up to 100 MHz, up to 1 GHz, up to 10 GHz, up to 100 GHz, or up to 500 GHz. It is also conceivable that different test signals having different frequencies may applied to the first resistor structure 40 simultaneously and/or consecutively.

At least one characteristic property of the first resistor structure 40 is determined based on the test signal applied to the first resistor structure 40 (step S7). In some embodiments, the measurement circuit 32 may measure a response of the first resistor structure 40 to the test signal in order to determine the at least one characteristic quantity. For example, the at least one characteristic quantity comprises a resistance of the first resistor structure 40. Accordingly, the measurement circuit 32 may be configured to determine the resistance of the at first resistor structure 40 based on the test signal applied to the first resistor structure 40.

The first resistor structure 40 is trimmed by the light source 26 until the at least one characteristic property has a predefined nominal value or differs from the predefined nominal value by less than a predefined threshold (step S8). In some embodiments, material is removed from the first resistor structure 40 by means of light emitted by the light source 26. This causes the at least one characteristic property to get closer to the predefined nominal value.

In some embodiments, the first resistor structure 40 may be trimmed until the resistance of the first resistor structure 40 is equal to a nominal resistance or deviates from the nominal resistance by less than a predefined resistance threshold.

Thus, before trimming, the resistance of the first resistor structure 40 may be smaller than the nominal value and may differ from the nominal value by more than the predefined resistance threshold.

By removing material from the first resistor structure 40 by the light, the resistance of the first resistor structure 40 is increased until the resistance of the first resistor structure 40 is equal to the nominal resistance or deviates from the nominal resistance by less than the predefined resistance threshold.

In some embodiments, the first resistor structure 40 may be trimmed in an area around the first end, such that a width of the first end is reduced.

In some embodiments, the first resistor structure 40 may be trimmed symmetrically with respect to an axis A of the first resistor structure 40 extending between the first end and the second end of the first resistor structure 40.

Thus, the first resistor structure 40 may be axially symmetric with respect to the axis A after trimming.

Steps S3 to S8 described above may be optionally repeated for a second resistor structure 54, a second contacting structure 56, and a second electric connection 58 (step S9). The second electric connection 58 is electrically connected to the second contacting structure 56 by a third via 60. Further, the second electric connection 58 is electrically connected to the second resistor structure 54 by a fourth via 62. Accordingly, the second contacting structure 56 is electrically connected to the signal conductor 38 by the third via 60, the second electric connection 58, the fourth via 62, and the second resistor structure 54.

In some embodiments, a first end of second resistor structure 54 contacts the fourth via 62, while a second end of the second resistor structure 54 that is opposite to the first end contacts the signal conductor 38 directly.

The explanations given above with respect to the first resistor structure 40, the first electric connection 44, and the first contacting structure 42 likewise apply to the second resistor structure 54, the second electric connection 58, and the second contacting structure 56.

In some embodiments, the first resistor structure 40 and the second resistor structure 54 may be trimmed such that a resistance of the first resistor structure 40 is equal to a resistance of the second resistor structure 54. However, the resistance of the first resistor structure 40 may also be different from the resistance of the second resistor structure 54.

After trimming of the first resistor structure 40 and the second resistor structure 54, the first electric connection 44 and the second electric connection 58 are electrically connected to the reference mass layer 46 (step S10).

If the reference mass layer 46 is already provided on the second side 30 of the substrate 22, the first electric connection 44 and the second electric connection 58 may be electrically connected to the reference mass layer 46 by applying a conductive glue, by soldering of a bonding wire, by soldering of a conductive plate, by soldering of a conductive film, by welding of a bonding wire, by welding of a conductive plate, and/or by welding of a conductive film.

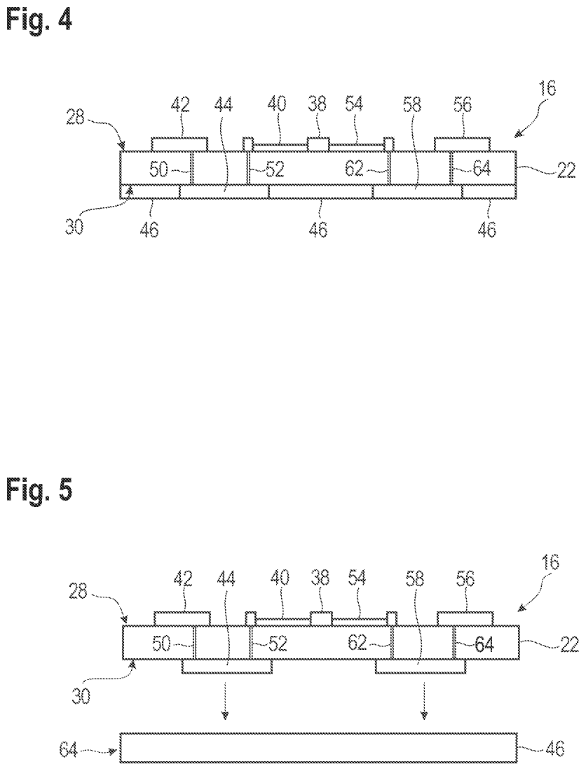

FIG. 4 shows a cross-sectional view of the electric circuit 16 along the axis A. As is shown in FIG. 4, a layer thickness of the signal conductor 38 may be larger than a layer thickness of the first resistor structure 40 and of the second resistor structure 54, respectively.

In some embodiments, a layer thickness of the first contacting structure 42, of the second contacting structure 56, of the first electric connection 44, of the second electric connection 58, and or of the reference mass layer 46 may be equal to the layer thickness of the signal conductor 38.

Another example embodiment of the electric circuit 16 manufactured by the method described above is schematically shown in FIG. 5. In this embodiment, the reference mass layer 46 is established as a conductive base body 64 that is provided separately from the substrate 22.

After trimming of the first resistor structure 40 and the second resistor structure 54, the first electric connection 44 and the second electric connection 58 are electrically connected to the reference mass layer 46 by attaching the second side 30 of the substrate 22 to the base body 64, as is indicated by the arrows in FIG. 5.

For example, the second side 30 of the substrate 22 may be glued to the base body 64 by a conductive glue. As another example, the substrate 22 may be screwed to the base body 64 with the second side 30 facing the base body 64. In a further example, the substrate 22 may be clamped onto the base body 64 with the second side 30 facing the base body 64, as another example, the substrate 22 may be soldered and/or welded onto the base body 64 with the second side 30 facing the base body 64. Therein, the first electric connection 44 and/or the second electric connection 58 may be electrically connected to the base body 64 by a solder joint and/or by a weld.

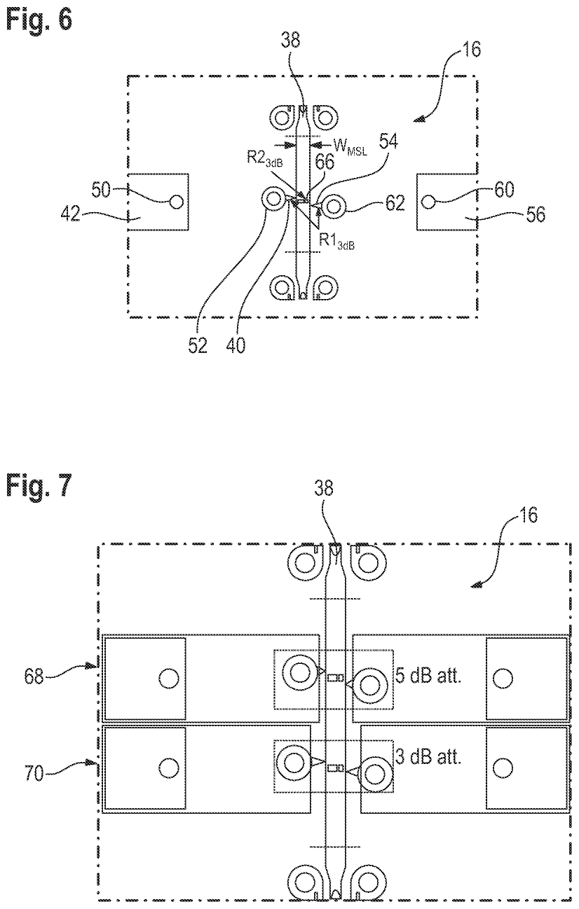

FIG. 6 shows another example embodiment of the electric circuit 16 manufactured by the method described above. In this embodiment, the electric circuit 16 is established as a x-attenuator, for example as a 3 dB attenuator.

In this embodiment, the first resistor structure 40 and the second resistor structure 54 are trimmed to have the same resistance R1. Further, a third resistor structure 66 having a resistance R2 is provided in the signal conductor 38 between a contact point of the first resistor structure 40 with the signal conductor 38 and a contact point of the second resistor structure 54 with the signal conductor 38.

In general, the resistance R2 may be different from the resistance R1. However, the resistance R2 may also be equal to the resistance R1. In some embodiments, the resistances of the first resistor structure 40, of the second resistor structure 54, and of the third resistor structure 66 are all pairwise different from each other, i.e. all resistances of the resistor structures 40, 54, 66 may be different from each other.

A further example embodiment of the electric circuit 16 manufactured by the method described above is shown in FIG. 7. Here, a first electric sub-circuit 68 and a second electric sub-circuit 70 are connected in series, thereby establishing an attenuator.

The electric sub-circuits 68, 70 are each established like the electric circuit 16 described above with respect to FIGS. 2 to 6. However, the resistances of the respective resistor structures may be trimmed to arbitrary values.

In the example shown in FIG. 7, the first sub-circuit is established as a 5 dB attenuator, while the second sub-circuit 70 is established as a 3 dB attenuator. Accordingly, as the electric sub-circuits 68, 70 are connected in series, the electric circuit 16 of FIG. 7 is an 8 dB attenuator.

Certain embodiments disclosed herein include systems, apparatus, modules, components, etc., such as the measurement circuit. The signal processing circuit, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof.

In an embodiment, circuitry includes hardware circuit implementations (e.g., implementations in analog circuitry, implementations in digital circuitry, and the like, and combinations thereof). In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure. Further, it will be appreciated that embodiments of the present disclosure may employ any combination of features described herein. All such combinations or sub-combinations of features are within the scope of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure. Further, it will be appreciated that embodiments of the present disclosure may employ any combination of features described herein. All such combinations or sub-combinations of features are within the scope of the present disclosure.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A method of manufacturing an electric circuit, the method comprising the steps of providing a substrate with a first side and a second side that is opposite to the first side;
providing a signal conductor on the first side of the substrate;
providing a first resistor structure on the first side of the substrate, wherein the first resistor structure contacts the signal conductor;
providing a first contacting structure on the first side of the substrate, wherein the first contacting structure is electrically connected to the first resistor structure by a first electric connection, such that the first contacting structure is electrically connected to the signal conductor via the first resistor structure, wherein the first electric connection is at least partially provided on the second side of the substrate;
applying a test signal to the first resistor structure via a measurement circuit contacting the first contacting structure and the signal conductor;
determining at least one characteristic property of the first resistor structure based on the test signal; and
trimming the first resistor structure until the at least one characteristic property has a predefined nominal value or differs from a predefined nominal value by less than a predefined threshold.

2. The method of claim 1, wherein the at least one characteristic property comprises a resistance.

3. The method of claim 1, wherein the first electric connection comprises at least one vertical interconnect access, via, that interconnects the first side of the substrate with the second side of the substrate through the substrate.

4. The method of claim 1, wherein the first resistor structure is trimmed by a laser.

5. The method of claim 1, wherein the first resistor structure has a first end and a second end that is opposite to the first end, wherein the first resistor structure tapers from the first end towards the second end.

6. The method of claim 5, wherein the first end is connected to the first contacting structure, and wherein the second end is directly connected to the signal conductor.

7. The method of claim 6, wherein the first resistor structure is trimmed in an area around the first end, such that a width of the first end is reduced.

8. The method of claim 5, wherein the first resistor structure is trimmed symmetrically with respect to an axis of the first resistor structure extending between the first end and the second end.

9. The method of claim 1, wherein the first resistor structure has a first end and a second end that is opposite to the first end, wherein the first resistor structure has a constant width between the first end and the second end.

10. The method of claim 1, wherein a layer thickness of the signal conductor is larger than a layer thickness of the first resistor structure.

11. The method of claim 1, wherein the first resistor structure is composed of a different material or different materials compared to the signal conductor.

12. The method of claim 1, wherein the signal conductor comprises or consists of gold, and/or wherein the first resistor structure comprises or consists of nickel and/or chrome.

13. The method of claim 1, wherein a reference mass layer is provided on the second side of the substrate, and wherein the first electric connection is electrically isolated from the reference mass layer during the trimming of the first resistor structure.

14. The method of claim 13, wherein a portion of the first electric connection provided on the second side of the substrate is electrically connected to the reference mass layer after trimming of the first resistor structure, wherein the portion of the first electric connection provided on the second side of the substrate is electrically connected to the reference mass layer by applying a conductive glue, by soldering of a bonding wire, by soldering of a conductive plate, by soldering of a conductive film, by welding of a bonding wire, by welding of a conductive plate, and/or by welding of a conductive film.

15. The method of claim 13, wherein the reference mass layer is established as a conductive base body that is provided separately from the substrate, wherein the second side of the substrate is attached to the base body after trimming of the first resistor structure, such that a portion of the first electric connection provided on the second side of the substrate is electrically connected to the base body.

16. The method of claim 15, wherein the second side of the substrate is glued to the base body by a conductive glue, and/or wherein the substrate is screwed onto the base body with the second side facing the base body.

17. The method of claim 15, wherein the substrate is clamped onto the base body with the second side facing the base body.

18. The method of claim 15, wherein the substrate is soldered and/or welded onto the base body with the second side facing the base body, wherein the portion of the first electric connection provided on the second side of the substrate is electrically connected to the base body by a solder joint and/or by a weld.

19. The method of claim 1, further comprising the steps of
providing a second resistor structure on the first side of the substrate, wherein the second resistor structure contacts the signal conductor;
providing a second contacting structure on the first side of the substrate, wherein the second contacting structure is electrically connected to the second resistor structure by a second electric connection, such that the second contacting structure is electrically connected to signal conductor via the second resistor structure, wherein the second electric connection is at least partially provided on a second side of the substrate;
applying a test signal to the second resistor structure via a measurement circuit contacting the second contacting structure and the signal conductor;
determining at least one characteristic property of the second resistor structure based on the test signal; and
trimming the second resistor structure until the at least one characteristic property has a nominal value or differs from the nominal value by less than a predefined threshold.

20. A test and/or measurement instrument, comprising an electric circuit manufactured according to the method of claim 1.
